(19) United States
(12) Patent Application Publication
(10) Pub. No.: US 2026/0106586 A1
(43) Pub. Date: Apr. 16, 2026

(54) HYBRID DIFFERENTIAL AMPLIFIER WITH LOW COST AND HIGH LINEARITY AND METHOD THEREOF

(71) Applicant: Richtek Technology Corporation, Hsinchu (TW)

(72) Inventors: Yi-Kuang CHEN, Hsinchu (TW); Shao-Ming SUN, Hsinchu (TW); Ming-Jun HSIAO, Hsinchu (TW)

(21) Appl. No.: 18/964,715

(22) Filed: Dec. 2, 2024

(30) Foreign Application Priority Data
Oct. 15, 2024 (TW) 113139195

(51) Int. Cl. H03F 3/45; H03F 1/08

(52) U.S. Cl. CPC H03F 3/45475; H03F 1/083; H03F 2203/45138

(57) ABSTRACT

A hybrid differential amplifier that generates a differential output signal based on a differential input signal to drive a load, includes: a first amplifier configured as an inductive switching converter to perform pulse-width modulation (PWM) conversion based on a first input signal of the differential input signal to switch an inductor and generate a first output signal of the differential output signal; and a second amplifier configured to generate a second output signal of the differential output signal based on a second input signal of the differential input signal. The second amplifier is configured as a different type of amplifier distinct from the inductive switching converter. The second amplifier further generates the second output signal based on feedback from the differential output signal, thereby the differential output signal being linearly correlated with the differential input signal.

### CROSS REFERENCE

The present invention claims priority to TW 113139195 filed on Oct. 15, 2024.

### BACKGROUND OF THE INVENTION

### Field of Invention

This invention relates to a differential amplifier, specifically to a differential amplifier capable of improving speed, linearity, and immunity to various filtering circuits (LC filters), using hybrid conversion schemes.

### Description of Related Art

Compared to Class A or Class AB amplifiers, traditional Class D amplifiers offer better efficiency. However, due to their switching characteristics, Class D amplifiers often require passive lossless LC filters to demodulate signals and limit bandwidth to reduce electromagnetic interference (EMI). The presence of inductors in LC filters leads to higher costs, larger size, and increased weight. In applications such as electric vehicles or true wireless earphones, removing inductors can reduce cost, size, and weight, while extending battery life.

Related prior art includes U.S. Patent US20230098806. FIG. 1 illustrates a simplified block diagram of an amplifier from the prior art. This prior art differential amplifier includes a first amplification circuit and a second amplification circuit, which respectively amplify the first input signal Vip and the second input signal Vin of the differential input signal, generating corresponding first output signal Vop and second output signal Von. The first amplification circuit is configured as a switching Class D converter, while the second amplification circuit is configured as an analog amplifier. Compared to traditional pure Class D amplifiers, this prior art removes an LC filter. However, in this prior art, the feedback loop filter for the output signal is configured within the switching first amplification stage circuit. This configuration results in the unity gain bandwidth being limited by the switching frequency.

In view of the shortcomings of the prior art, this invention proposes a hybrid differential amplifier that balances the aforementioned demands.

### SUMMARY OF THE INVENTION

The advantages of this invention lie in its ability to reduce inductor current ripple, support multiple input sources (multi-stage), implement with switched capacitor regulators, and incorporate local feedback and filters. These features enhance speed, linearity, and immunity to various filtering circuits (LC filters).

From one perspective, the present invention provides a hybrid differential amplifier for generating a differential output signal based on a differential input signal to drive a load. The hybrid differential amplifier comprises a first amplifier, configured as an inductive switching converter, to perform pulse-width modulation (PWM) conversion based on a first input signal of the differential input signal to switch an inductor and generate a first output signal of the differential output signal; and a second amplifier, configured to generate a second output signal of the differential output signal based on a second input signal of the differential input signal, wherein the second amplifier is configured as a type of amplifier distinct from the inductive switching converter; and wherein the second amplifier further generates the second output signal based on feedback from the differential output signal, thereby rendering the differential output signal linearly correlated with the differential input signal.

In one preferred embodiment, the first amplifier comprises a signal adjustment circuit configured to apply distortion processing to the first input signal to generate a distortion amplification signal; a first pulse-width modulation circuit configured to generate a PWM output signal based on a comparison between the distortion amplification signal and a first triangular wave; and a switching power stage circuit configured to switch the inductor based on the PWM output signal to generate the first output signal, wherein the distortion processing includes amplifying and clamping one of the first input signal or the second input signal to generate a saturated amplification signal, and linearly superposing the first input signal with the saturated amplification signal to generate the distortion amplification signal.

In one preferred embodiment, the second amplifier is configured as a linear amplifier operating in the continuous time domain and includes a loop filter circuit configured to linearly integrate the difference between the differential output signal and the differential input signal to generate a loop filter signal; a gain stage circuit configured to linearly amplify the loop filter signal to generate a gain output signal; and an amplification stage circuit configured to linearly amplify the gain output signal to generate the second output signal.

In one preferred embodiment, the second amplifier further includes an adder configured to superpose the saturated amplification signal and the loop filter signal; wherein the gain stage circuit is further configured to amplify the superposition of the saturated amplification signal and the loop filter signal to generate the gain output signal; and wherein a difference between the distortion amplification signal and the gain output signal is linearly correlated with the differential input signal.

In one preferred embodiment, the second output signal is fed back from the amplification stage circuit to the gain stage circuit; and the gain stage circuit is further configured to generate the gain output signal based on a difference between a feedback signal related to the second output signal and the loop filter signal.

In one preferred embodiment, the signal adjustment circuit is configured in one of the following configurations:

Configuration I: The signal adjustment circuit includes an in-phase amplification circuit and a clamping circuit, wherein the in-phase amplification circuit is configured to amplify one of the first input signal or the second input signal to generate an in-phase amplified signal; and the clamping circuit is configured to limit the in-phase amplified signal within a predetermined range to generate the distortion amplification signal.

Configuration II: The signal adjustment circuit includes an in-phase amplification circuit, a clamping circuit, and an inverted amplification circuit, wherein the in-phase amplification circuit is configured to amplify one of the first input signal or the second input signal to generate an in-phase amplified signal; the clamping circuit is configured to limit the in-phase amplified signal within a predetermined range to generate a saturated amplification signal; and the inverted amplification circuit is configured to amplify the saturated amplification signal to generate the distortion amplification signal.

Configuration III: The signal adjustment circuit includes an in-phase amplification circuit, a clamping circuit, and an inverted adder circuit, wherein the in-phase amplification circuit is configured to amplify one of the first input signal or the second input signal to generate an in-phase amplified signal; the clamping circuit is configured to limit the in-phase amplified signal within a predetermined range to generate a saturated amplification signal; and the inverted adder circuit is configured to superpose the saturated amplification signal with the other of the first input signal or the second input signal to generate the distortion amplification signal.

In one preferred embodiment, the amplification stage circuit includes a Class AB amplifier which includes an upper transistor and a lower transistor; and a level shifter, wherein the first and second ends of the level shifter are respectively configured to couple to the gate of the upper transistor and the gate of the lower transistor to maintain a preset voltage difference between the gates of the upper and lower transistors; wherein the upper transistor and the lower transistor are connected in series and configured to generate the second output signal; and wherein the level shifter is further configured to shift the level of the gain output signal to control the gates of the upper and lower transistors.

In one preferred embodiment, the first pulse-width modulation circuit is configured to compare the distortion amplification signal with the first triangular wave to generate a first PWM signal, wherein the distortion amplification signal and the first triangular wave share the same common-mode level. The hybrid differential amplifier further comprises a second pulse-width modulation circuit configured to generate a second PWM signal based on a comparison between the distortion amplification signal and a second triangular wave, wherein a common-mode level of the first triangular wave and a common-mode level of the second triangular wave have a non-zero offset; a load detection circuit configured to determine whether the hybrid differential amplifier is in a light-load state or a non-light-load state and to generate a corresponding selection signal; and an output selection circuit configured to select the second PWM signal as the PWM output signal during the light-load state and select the first PWM signal as the PWM output signal during the non-light-load state.

In one preferred embodiment, the first pulse-width modulation circuit is configured to compare the distortion amplification signal with the first triangular wave to generate a first PWM signal. The hybrid differential amplifier further comprises a second pulse-width modulation circuit configured to generate a second PWM signal based on a comparison between the distortion amplification signal and a second triangular wave, wherein an amplitude of the first triangular wave is greater than an amplitude of the second triangular wave; a load detection circuit configured to determine whether the hybrid differential amplifier is in a light-load state or a non-light-load state and to generate a corresponding selection signal; and an output selection circuit configured to select the first PWM signal as the PWM output signal during the non-light-load state and control the switching power stage circuit to switch the inductor with a first amplitude to generate the first output signal, and select the second PWM signal as the PWM output signal during the light-load state and control the switching power stage circuit to switch the inductor with a second amplitude to generate the first output signal; wherein the first amplitude is greater than the second amplitude.

In one preferred embodiment, the second amplifier is configured as a switched capacitor converter, and the switched capacitor converter includes a loop filter circuit configured to integrate a difference between the differential output signal and the differential input signal to generate a loop filter signal; a gain stage circuit configured to amplify a difference between the loop filter signal and a feedback signal related to the second output signal to generate a gain output signal; a pulse-width modulation circuit configured to generate plural PWM signals based on a comparison between the gain output signal and plural ramp signals; and a switched-capacitor power stage circuit, including plural switches configured to control switching of at least one capacitor based on the plural PWM signals to generate the second output signal through switched-capacitor power conversion.

From another perspective, the present invention provides a hybrid differential amplification method for generating a differential output signal based on a differential input signal to drive a load. The method comprises performing pulse-width modulation (PWM) conversion based on a first input signal of the differential input signal to switch an inductor to generate a first output signal of the differential output signal; generating a second output signal of the differential output signal based on a second input signal of the differential input signal, wherein the generation of the second output signal does not involve switching the inductor; and generating the second output signal based on feedback from the differential output signal, thereby rendering the differential output signal linearly correlated with the differential input signal.

In one preferred embodiment, the step of generating the first output signal includes applying distortion processing to the first input signal to generate a distortion amplification signal; generating a PWM output signal based on a comparison between the distortion amplification signal and a first triangular wave; and switching the inductor based on the PWM output signal to generate the first output signal, wherein the distortion processing includes amplifying and clamping one of the first input signal or the second input signal to generate a saturated amplification signal, and linearly superposing the first input signal with the saturated amplification signal to generate the distortion amplification signal.

In one preferred embodiment, the step of generating the second output signal includes linearly integrating a difference between the differential output signal and the differential input signal to generate a loop filter signal; linearly amplifying the loop filter signal to generate a gain output signal; and linearly amplifying the gain output signal to generate the second output signal.

In one preferred embodiment, the step of generating the second output signal further includes amplifying the superposition of the saturated amplification signal and the loop filter signal to generate the gain output signal, wherein a difference between the distortion amplification signal and the gain output signal is linearly correlated with the differential input signal.

In one preferred embodiment, the step of generating the second output signal further includes generating the gain output signal further based on a difference between a feedback signal related to the second output signal and the loop filter signal.

In one preferred embodiment, the step of generating the distortion amplification signal comprises one of the following: amplifying one of the first input signal or the second input signal to generate an in-phase amplified signal, and limiting the in-phase amplified signal within a predetermined range to generate the distortion amplification signal; amplifying one of the first input signal or the second input signal to generate an in-phase amplified signal, limiting the in-phase amplified signal within a predetermined range to generate a saturated amplification signal, and amplifying the saturated amplification signal to generate the distortion amplification signal; or amplifying one of the first input signal or the second input signal to generate an in-phase amplified signal, limiting the in-phase amplified signal within a predetermined range to generate a saturated amplification signal, and superposing the saturated amplification signal with the other of the first input signal or the second input signal to generate the distortion amplification signal.

In one preferred embodiment, the step of generating the second output signal includes controlling a Class AB amplifier using the gain output signal, wherein the Class AB amplifier includes an upper transistor and a lower transistor; controlling the Class AB amplifier includes shifting the level of the gain output signal to control the gates of the upper and lower transistors; and maintaining a preset voltage difference between the gates of the upper and lower transistors.

In one preferred embodiment, the step of generating the first output signal further includes generating a first PWM signal by comparing the distortion amplification signal with the first triangular wave, wherein the distortion amplification signal and the first triangular wave have the same common-mode level; generating a second PWM signal by comparing the distortion amplification signal with a second triangular wave, wherein the common-mode level of the first triangular wave and a common-mode level of the second triangular wave have a non-zero offset; determining whether the differential input signal is in a light-load state or a non-light-load state; and selecting the second PWM signal as the PWM output signal during the light-load state and selecting the first PWM signal as the PWM output signal during the non-light-load state.

In one preferred embodiment, the step of generating the first output signal further includes generating a first PWM signal by comparing the distortion amplification signal with the first triangular wave; generating a second PWM signal by comparing the distortion amplification signal with a second triangular wave, wherein the amplitude of the first triangular wave is greater than the amplitude of the second triangular wave; determining whether the differential input signal is in a light-load state or a non-light-load state; selecting the first PWM signal as the PWM output signal during the non-light-load state and switching the inductor with a first amplitude to generate the first output signal; and selecting the second PWM signal as the PWM output signal during the light-load state and switching the inductor with a second amplitude to generate the first output signal; wherein the first amplitude is greater than the second amplitude.

In one preferred embodiment, the step of generating the second output signal further includes integrating a difference between the differential output signal and the differential input signal to generate a loop filter signal; amplifying the difference between the loop filter signal and a feedback signal related to the second output signal to generate a gain output signal; generating plural PWM signals based on a comparison between the gain output signal and plural ramp signals; and controlling plural switches based on the plural PWM signals to switch at least one capacitor, thereby generating the second output signal through switched-capacitor power conversion.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a prior art amplifier.

FIG. 2 shows a circuit block diagram of a hybrid differential amplifier according to one embodiment of the present invention.

FIG. 3A shows a circuit block diagram of a hybrid differential amplifier according to one embodiment of the present invention.

FIG. 3B shows a circuit block diagram of the loop filter circuit of the hybrid differential amplifier according to one embodiment of the present invention.

FIGS. 4A and 4B show schematic diagrams of the signal adjustment circuit of the hybrid differential amplifier according to embodiments of the present invention.

FIG. 4C shows a schematic diagram of the signal adjustment circuit of the hybrid differential amplifier according to one embodiment of the present invention.

FIG. 4D shows a schematic waveform diagram of signals related to the signal adjustment circuit of the hybrid differential amplifier according to one embodiment of the present invention.

FIG. 5 shows a circuit block diagram of the hybrid differential amplifier according to another embodiment of the present invention.

FIG. 6 shows a circuit block diagram of the hybrid differential amplifier according to yet another embodiment of the present invention.

FIG. 7 shows a schematic diagram of the amplifier stage circuit of the hybrid differential amplifier according to one embodiment of the present invention.

FIGS. 8A and 8B show schematic diagrams of the gain stage circuit and the amplifier stage circuit of the hybrid differential amplifier according to embodiments of the present invention.

FIG. 9A shows a circuit block diagram of the hybrid differential amplifier according to still another embodiment of the present invention.

FIG. 9B shows a schematic waveform diagram of signals related to the hybrid differential amplifier in FIG. 9A according to one embodiment of the present invention.

FIG. 9C shows a schematic diagram of the amplifier stage circuit of the hybrid differential amplifier in FIG. 9A according to one embodiment of the present invention.

FIG. 10A shows a circuit block diagram of the hybrid differential amplifier according to yet another embodiment of the present invention.

FIG. 10B shows a schematic waveform diagram of signals related to the hybrid differential amplifier in FIG. 10A according to one embodiment of the present invention.

FIG. 10C shows a schematic diagram of the amplifier stage circuit of the hybrid differential amplifier in FIG. 10A according to one embodiment of the present invention.

FIG. 11A shows a schematic diagram of the amplifier circuit of the hybrid differential amplifier according to still another embodiment of the present invention.

FIG. 11B shows a schematic waveform diagram of signals related to the amplifier of the hybrid differential amplifier in FIG. 11A according to one embodiment of the present invention.

FIG. 12 shows a schematic waveform diagram of signals related to the hybrid differential amplifier according to one embodiment of the present invention.

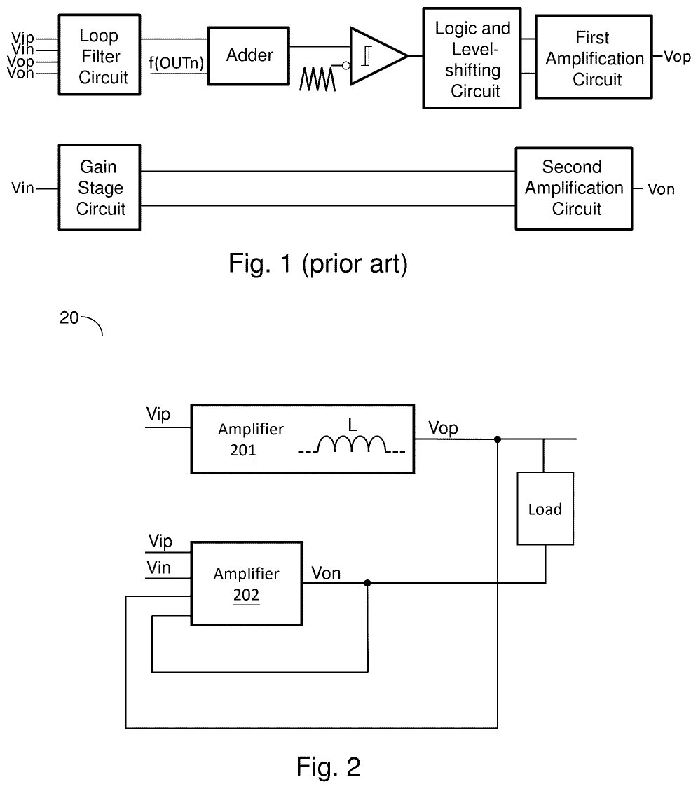

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

FIG. 2 shows a circuit block diagram of a hybrid differential amplifier according to one embodiment of the present invention. As shown in FIG. 2, the hybrid differential amplifier 20 generates a differential output signal Vod based on a differential input signal Vid to drive a load. The hybrid differential amplifier 20 includes amplifiers 201 and 202. Amplifier 201 performs pulse-width modulation (PWM) conversion based on the first input signal (e.g., Vip) of the differential input signal Vid to switch an inductor L and generate the first output signal Vop of the differential output signal Vod. In one embodiment, amplifier 201 is configured as an inductive switching converter. Amplifier 202 generates the second output signal Von of the differential output signal Vod based on the second input signal (e.g., Vin) of the differential input signal Vid. In one embodiment, amplifier 202 is configured as a different type of amplifier distinct from the inductive switching converter. Amplifier 202 further generates the second output signal Von based on feedback from the differential output signal Vod, thereby rendering the differential output signal Vod linearly correlated with the differential input signal Vid. In one embodiment, the differential input signal Vid represents the difference between the first input signal Vip and the second input signal Vin, while the differential output signal Vod represents the difference between the first output signal Vop and the second output signal Von.

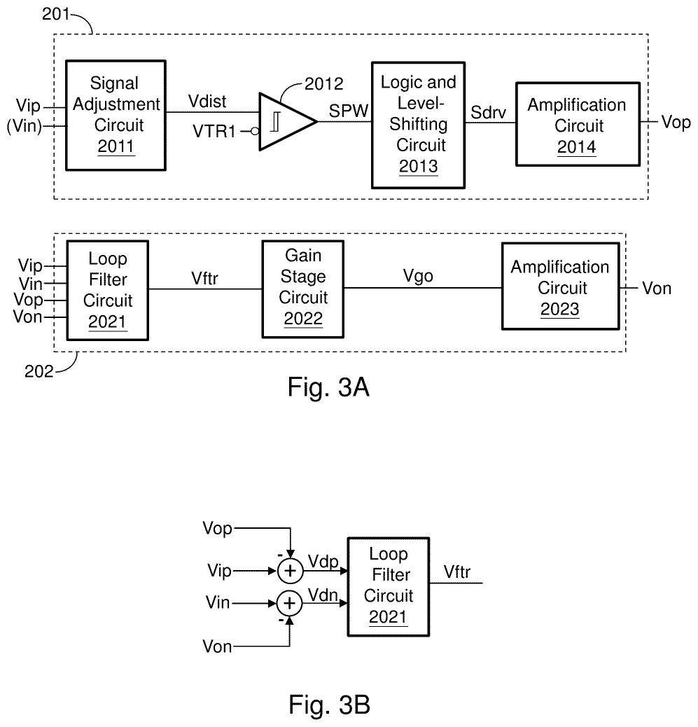

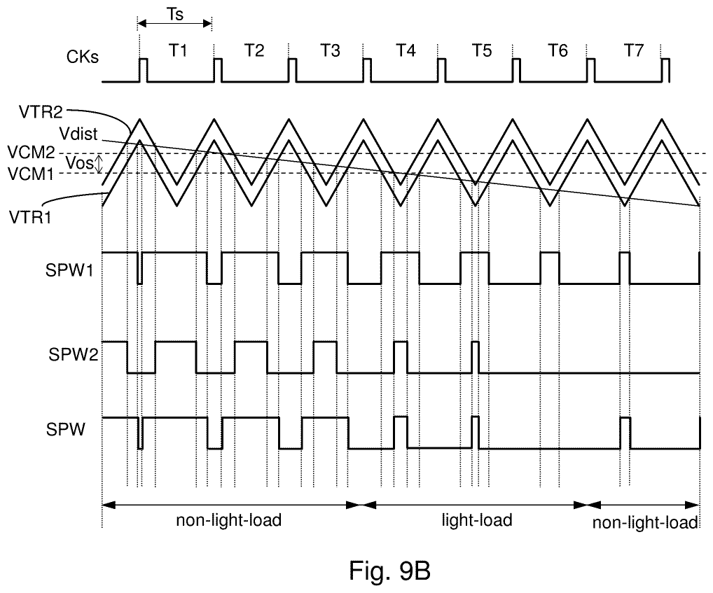

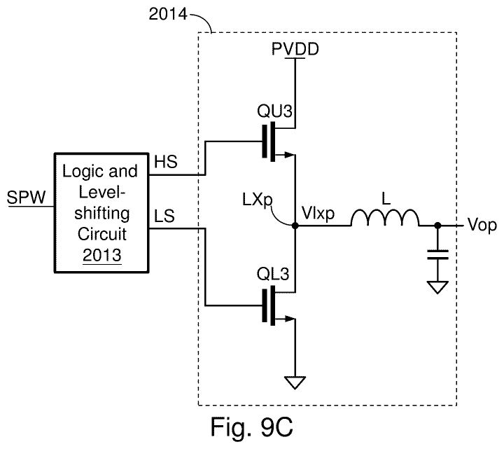

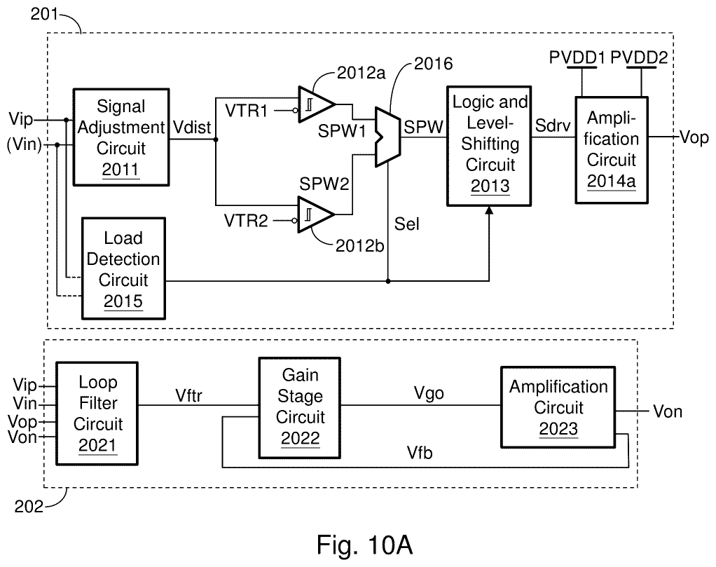

FIG. 3A shows a circuit block diagram of a hybrid differential amplifier according to one embodiment of the present invention. As shown in FIG. 3A, amplifier 201 includes a signal adjustment circuit 2011, a pulse-width modulation circuit 2012, a logic and level-shifting circuit 2013, and an amplification stage circuit 2014. The signal adjustment circuit 2011 applies distortion processing to the first input signal Vip to generate a distortion amplification signal Vdist. In one embodiment, the distortion processing involves amplifying and clamping one of the input signals (Vip or Vin) to generate a saturated amplification signal, which is then linearly superposed with the first input signal Vip to generate the distortion amplification signal Vdist. The PWM circuit 2012 compares the distortion amplification signal Vdist with a triangular wave VTR1 to generate a PWM output signal SPW. The logic and level-shifting circuit 2013 generates a drive signal Sdrv for the amplification stage circuit 2014 based on the PWM output signal SPW and shifts the level of Sdrv to the required operating range of the amplification stage circuit 2014. In one embodiment, the amplification stage circuit 2014 is a switching power stage circuit. The amplification stage circuit 2014 switches the inductor L according to the drive signal Sdrv (detailed in FIG. 9) to generate the first output signal Vop.

In one embodiment, amplifier 202 is configured as a linear amplifier operating in the continuous time domain. Amplifier 202 includes a loop filter circuit 2021, a gain stage circuit 2022, and an amplification stage circuit 2023. The loop filter circuit 2021 linearly integrates the difference between the differential output signal Vod and the differential input signal Vid to generate a loop filter signal Vftr. The gain stage circuit 2022 linearly amplifies the loop filter signal Vftr to generate a gain output signal Vgo. The amplification stage circuit 2023 linearly amplifies the gain output signal Vgo to generate the second output signal Von. In one embodiment, the difference between the distortion amplification signal Vdist and the gain output signal Vgo is linearly correlated with the differential input signal Vid.

FIG. 3B shows a circuit block diagram of the loop filter circuit of the hybrid differential amplifier according to one embodiment of the present invention. This embodiment is an example of the loop filter circuit 2021 from FIG. 3A. As shown in FIG. 3B, the loop filter circuit 2021 generates a loop filter signal Vftr based on the difference Vdp between the first input signal Vip and the first output signal Vop, and the difference Vdn between the second input signal Vin and the second output signal Von. FIG. 3B illustrates an exemplary embodiment and does not limit the methods for obtaining the difference between the differential output signal Vod and the differential input signal Vid.

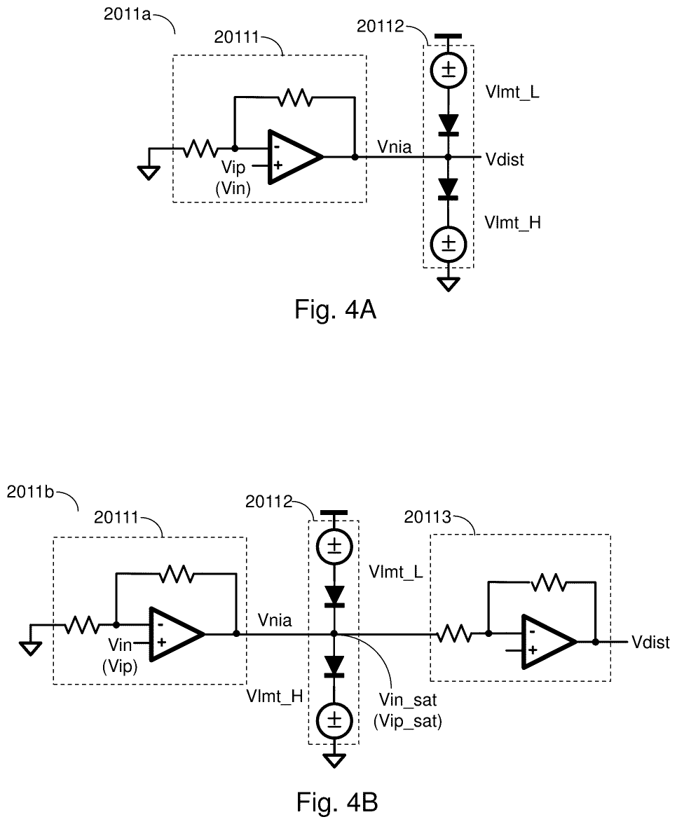

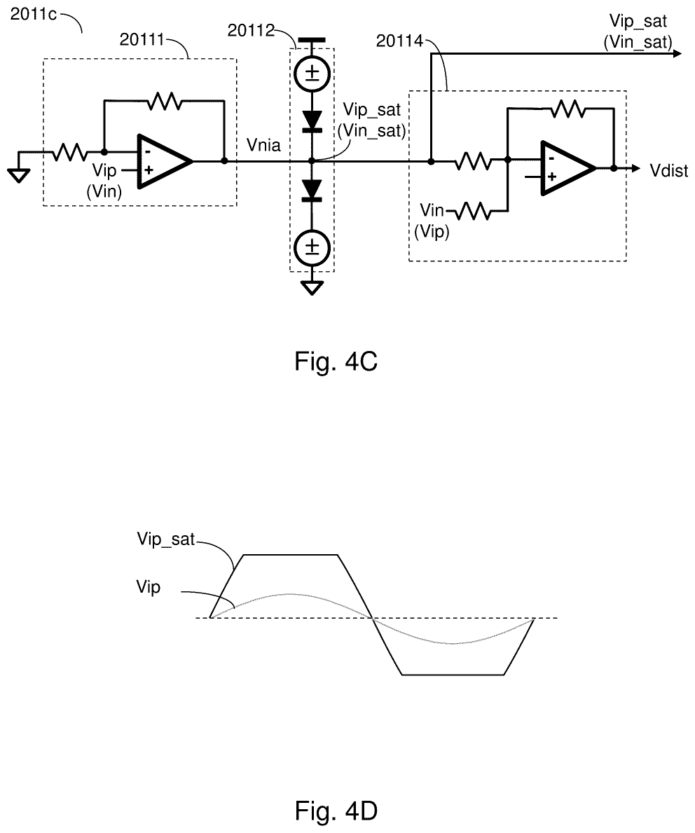

FIGS. 4A and 4B show schematic diagrams of the signal adjustment circuit of the hybrid differential amplifier according to embodiments of the present invention. In one embodiment, as shown in FIG. 4A, the signal adjustment circuit 2011a includes an in-phase amplification circuit 20111 and a clamping circuit 20112. The in-phase amplification circuit 20111 amplifies one of the first input signal Vip or the second input signal Vin to generate an in-phase amplified signal Vnia. The clamping circuit 20112 limits the in-phase amplified signal Vnia within a predetermined range, such as but not limited to an upper limit Vlmt_H and a lower limit Vlmt_L, to generate the distortion amplification signal Vdist. As shown in FIG. 4B, in another embodiment, the signal adjustment circuit 2011b includes the in-phase amplification circuit 20111, the clamping circuit 20112, and an inverted amplification circuit 20113. The in-phase amplification circuit 20111 and clamping circuit 20112 in this embodiment are similar to those in FIG. 4A and are thus not described in detail. The inverted amplification circuit 20113 amplifies the saturated amplification signal Vin_sat or Vip_sat generated by the clamping circuit 20112 to generate the distortion amplification signal Vdist.

FIG. 4C shows a schematic diagram of the signal adjustment circuit of the hybrid differential amplifier according to one embodiment of the present invention. In yet another embodiment, as shown in FIG. 4C, the signal adjustment circuit 2011c includes the in-phase amplification circuit 20111, the clamping circuit 20112, and an inverted adder circuit 20114. The in-phase amplification circuit 20111 and clamping circuit 20112 in this embodiment are similar to those in FIG. 4A and are thus not described in detail. The inverted adder circuit 20114 superposes the saturated amplification signal Vin_sat or Vip_sat generated by the clamping circuit 20112 with another input signal from Vip or Vin to generate the distortion amplification signal Vdist. In a specific embodiment corresponding to the amplifier 201 in FIG. 3A, the distortion amplification signal Vdist can be a superposition of the first input signal Vip and the saturated amplification signal Vin_sat. Consequently, the second output signal Von is generated via feedback control by the loop filter circuit 2021, resulting in a waveform corresponding to the saturated amplification signal Vin_sat (see FIG. 12).

FIG. 4D shows a schematic waveform diagram of signals related to the signal adjustment circuit of the hybrid differential amplifier according to one embodiment of the present invention. The saturated amplification signal Vip_sat and the first input signal Vip are shown in FIG. 4D.

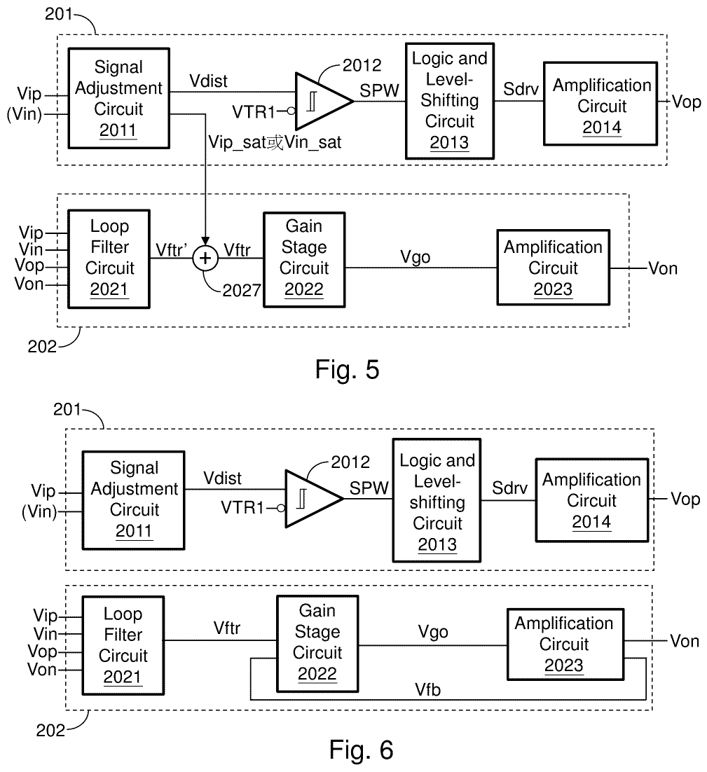

FIG. 5 shows a circuit block diagram of a hybrid differential amplifier according to another embodiment of the present invention. As shown in FIG. 5, this embodiment is similar to the embodiment in FIG. 3A, and differs in that amplifier 202 in this embodiment further includes an adder 2027. The adder 2027 superposes the saturated amplification signal Vip_sat or Vin_sat with the loop filter signal Vftr′ to generate a combined loop filter signal Vftr. In this embodiment, the gain stage circuit 2022 amplifies the combined loop filter signal Vftr to generate the gain output signal Vgo. By pre-superposing the saturated amplification signal Vip_sat or Vin_sat with the loop filter signal Vftr', the required signal range within the loop filter circuit 2021 can be reduced, thereby lowering the demands on bandwidth, gain, or slew rate of the loop filter circuit 2021.

FIG. 6 shows a circuit block diagram of a hybrid differential amplifier according to yet another embodiment of the present invention. As shown in FIG. 6, this embodiment is similar to the embodiment in FIG. 3A, and differs in that in this embodiment, the second output signal Von is fed back to the gain stage circuit 2022 from the amplification stage circuit 2023. The gain stage circuit 2022 generates the gain output signal Vgo by amplifying the difference between the feedback signal Vfb, which is related to the second output signal Von, and the loop filter signal Vftr.

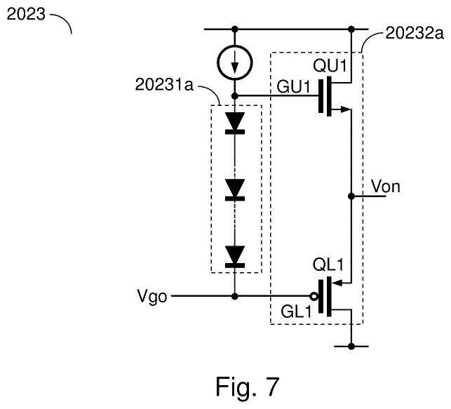

FIG. 7 shows a schematic diagram of the amplification stage circuit of the hybrid differential amplifier according to one embodiment of the present invention. This embodiment is an example of the amplification stage circuit 2023. As shown in FIG. 7, the amplification stage circuit 2023 includes a level shifter 20231a and a Class AB amplifier 20232a. The Class AB amplifier 20232a includes an upper transistor QU1 and a lower transistor QL1. The first and second ends of the level shifter 20231a are coupled to the gates of the upper transistor QU1 and the lower transistor QL1, respectively, to maintain a preset voltage difference between their gates. The upper transistor QU1 and the lower transistor QL1 are connected in series to generate the second output signal Von. An input terminal of the level shifter 20231a is coupled to the gain output signal Vgo. In this embodiment, the gain output signal Vgo is coupled to control the gate of the lower transistor QL1. The level-shifted gain output signal Vgo′ is coupled to control the gate of the upper transistor QU1. The level shifter 20231a in this embodiment may include multiple diodes to provide a level-shifting voltage.

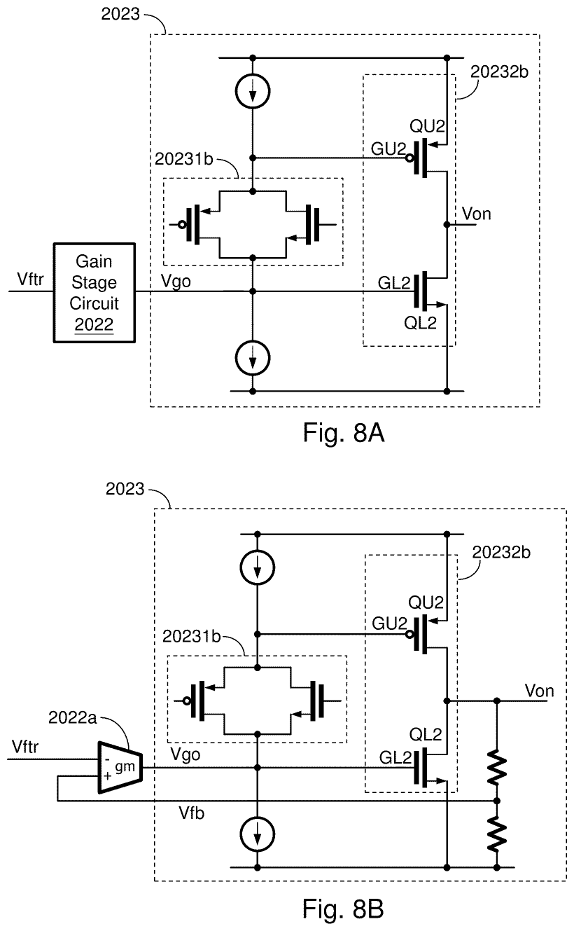

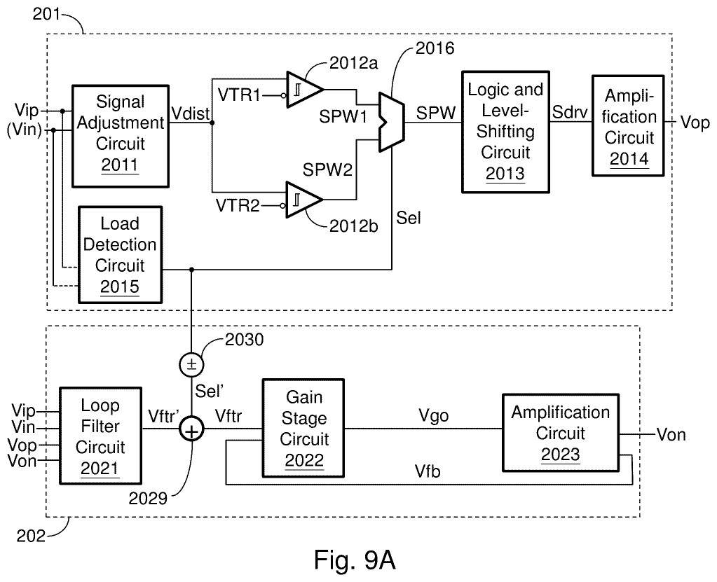

FIG. 8A shows a schematic diagram of the gain stage circuit and the amplification stage circuit of the hybrid differential amplifier according to one embodiment of the present invention. This embodiment is another example of the amplification stage circuit 2023. As shown in FIG. 8A, the amplification stage circuit 2023 includes a Class AB amplifier 20232b and a level shifter 20231b. The Class AB amplifier 20232b includes an upper transistor QU2 and a lower transistor QL2. The first and second ends of the level shifter 20231b are coupled to the gates of the upper transistor QU2 and the lower transistor QL2, respectively, to maintain a preset voltage difference between their gates. The upper transistor QU2 and the lower transistor QL2 are connected in series to generate the second output signal Von. The second end of the level shifter 20231b is coupled to the gain stage circuit 2022. In this embodiment, the level shifter 20231b may include two complementary transistors connected in parallel to provide a level-shifting voltage.

FIG. 8B shows a schematic diagram of the gain stage circuit and the amplification stage circuit of the hybrid differential amplifier according to one embodiment of the present invention. This embodiment is a specific example of FIG. 8A, where the gain stage circuit is a local feedback amplifier 2022a. The local feedback amplifier 2022a amplifies the difference between the loop filter signal Vftr and the feedback signal Vfb to generate the gain output signal Vgo. The feedback signal Vfb is related to the second output signal Von, for example, as a divided voltage of the second output signal Von.

FIG. 9A shows a circuit block diagram of a hybrid differential amplifier according to still another embodiment of the present invention. This embodiment is similar to the embodiment in FIG. 6, and differs in that, as shown in FIG. 9A, amplifier 201 includes pulse-width modulation circuits 2012a and 2012b, a load detection circuit 2015, and an output selection circuit 2016, while amplifier 202 includes an adder 2029 and a common-mode shifter 2030. The pulse-width modulation circuit 2012a compares the distortion amplification signal Vdist with a triangular wave VTR1 to generate the PWM signal SPW1. In one embodiment, the distortion amplification signal Vdist and the triangular wave VTR1 share the same common-mode level VCM1. The pulse-width modulation circuit 2012b compares the distortion amplification signal Vdist with a triangular wave VTR2 to generate the PWM signal SPW2. Referring to both FIG. 9A and FIG. 9B, the common-mode level VCM1 of the triangular wave VTR1 and the common-mode level VCM2 of the triangular wave VTR2 have a non-zero offset Vos. The load detection circuit 2015 determines whether the hybrid differential amplifier 20 is in a light-load or non-light-load state based on the levels of the differential input signals (Vip and/or Vin) and generates a selection signal Sel representing corresponding states. The output selection circuit 2016 selects the PWM signal SPW2 as the PWM output signal SPW when the selection signal Sel indicates a light-load state, and selects the PWM signal SPW1 as the PWM output signal SPW when the selection signal Sel indicates a non-light-load state. The common-mode shifter 2030 offsets the selection signal Sel by a shift voltage to generate a level-adjusted signal Sel′. The adder 2029 superposes the loop filter signal Vftr′ and the level-adjusted signal Sel′ to generate the combined loop filter signal Vftr.

FIG. 9B shows a schematic waveform diagram of signals related to the hybrid differential amplifier in FIG. 9A according to one embodiment of the present invention. The clock signals CKs, triangular waves VTR1 and VTR2, the distortion amplification signal Vdist, common-mode levels VCM1 and VCM2, the offset Vos, and the PWM signals SPW, SPW1, and SPW2 are shown in FIG. 9B. FIG. 9C shows a schematic diagram of the amplification stage circuit of the hybrid differential amplifier in FIG. 9A according to one embodiment of the present invention. As shown in FIG. 9C, the amplification stage circuit 2014 includes an upper switch QU3, a lower switch QL3, and an inductor L. The upper switch QU3 is coupled between the power supply voltage PVDD and the switching node LXp, while the lower switch QL3 is coupled between the switching node LXp and ground. The inductor L is coupled between the switching node LXp and the first output signal Vop. Referring to both FIGS. 9B and 9C, the logic and level-shifting circuit 2013 generates drive signals HS and LS based on the PWM signal SPW to control the upper switch QU3 and the lower switch QL3, thereby causing the switching node voltage Vlxp to alternate between the power supply voltage PVDD and ground.

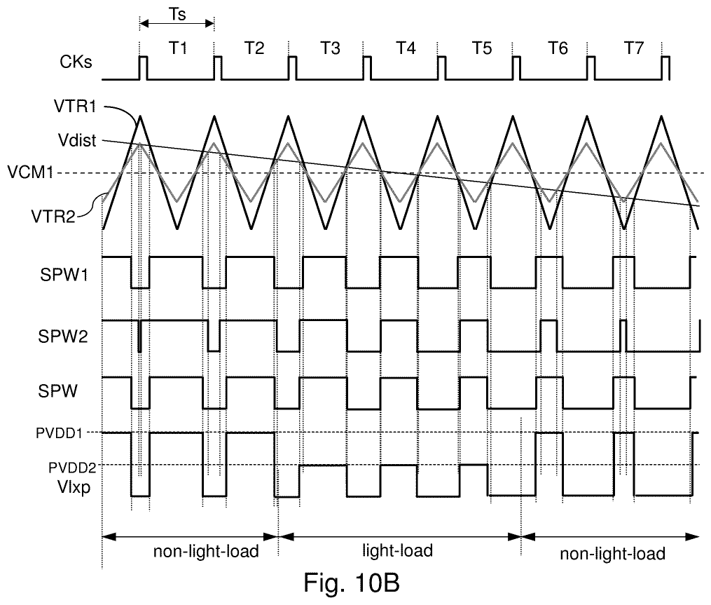

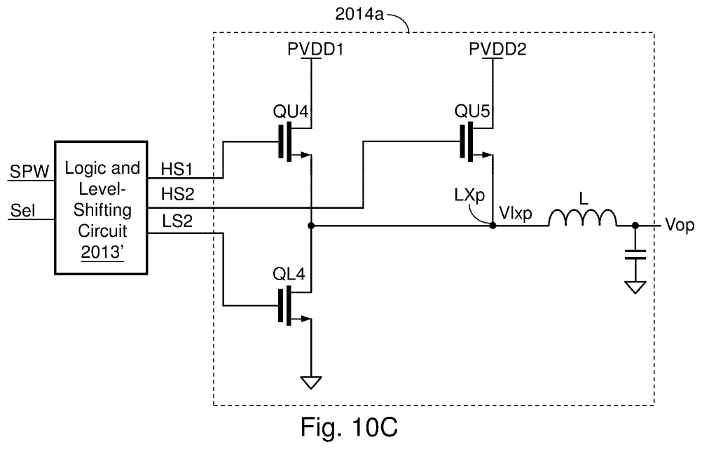

FIG. 10A shows a circuit block diagram of a hybrid differential amplifier according to yet another embodiment of the present invention. FIG. 10B shows a schematic waveform diagram of signals related to the hybrid differential amplifier in FIG. 10A according to one embodiment of the present invention. The clock signals CKs, triangular waves VTR1 and VTR2, the distortion amplification signal Vdist, common-mode level VCM1, PWM signals SPW, SPW1, and SPW2, and the first output signal Vop are shown in FIG. 10B. This embodiment is similar to the embodiment in FIG. 6, and differs in that, as shown in FIG. 10A, amplifier 201 includes pulse-width modulation circuits 2012a and 2012b, a load detection circuit 2015, and an output selection circuit 2016. The pulse-width modulation circuit 2012a compares the distortion amplification signal Vdist with the triangular wave VTR1 to generate the PWM signal SPW1, while the pulse-width modulation circuit 2012b compares the distortion amplification signal Vdist with the triangular wave VTR2 to generate the PWM signal SPW2. In one embodiment, the amplitude of the triangular wave VTR1 is greater than that of the triangular wave VTR2 (as shown in FIG. 10B). The load detection circuit 2015 determines whether the hybrid differential amplifier 20 is in a light-load or non-light-load state based on the levels of the first input signal Vip and/or the second input signal Vin and generates a corresponding selection signal Sel. The output selection circuit 2016 selects the PWM signal SPW2 as the PWM output signal SPW during a light-load state and drives the amplification stage circuit 2014a to switch the inductor L with a switching node voltage Vlxp having one amplitude (i.e., PVDD2), thereby generating the first output signal Vop. On the other hand, the output selection circuit 2016 selects the PWM signal SPW1 as the PWM output signal SPW during a non-light-load state and drives the amplification stage circuit 2014a to switch the inductor L with a switching node voltage Vlxp having another amplitude (i.e., PVDD1), thereby generating the first output signal Vop. In one embodiment, PVDD1 is greater than PVDD2.

FIG. 10C shows a schematic diagram of the amplification stage circuit of the hybrid differential amplifier in FIG. 10A according to one embodiment of the present invention. As shown in FIG. 10C, the amplification stage circuit 2014a includes upper switches QU4 and QU5, a lower switch QL4, and an inductor L. The upper switch QU4 is coupled between the power supply voltage PVDD1 and the switching node LXp, the upper switch QU5 is coupled between the power supply voltage PVDD2 and the switching node LXp, and the lower switch QL4 is coupled between the switching node LXp and ground. The inductor L is coupled between the switching node LXp and the first output signal Vop. Referring to FIGS. 10A, 10B, and 10C, the logic and level-shifting circuit 2013′ generates drive signals HS1, HS2, and LS based on the PWM signal SPW and the selection signal Sel to control the upper switches QU4 and QU5 and the lower switch QL4. When the load detection circuit 2015 determines that the hybrid differential amplifier 20 is in a non-light-load state, the drive signals HS1 and LS periodically switch the upper switch QU4 and the lower switch QL4 based on the PWM signal SPW, causing the switching node voltage Vlxp to alternate between the power supply voltage PVDD1 and ground, while the drive signal HS2 keeps the upper switch QU5 off. Conversely, when the load detection circuit 2015 determines that the hybrid differential amplifier 20 is in a light-load state, the drive signals HS2 and LS periodically switch the upper switch QU5 and the lower switch QL4 based on the PWM signal SPW, causing the switching node voltage Vlxp to alternate between the power supply voltage PVDD2 and ground, while the drive signal HS1 keeps the upper switch QU4 off. As shown in FIG. 10B, the power supply voltage PVDD2 is lower than PVDD1.

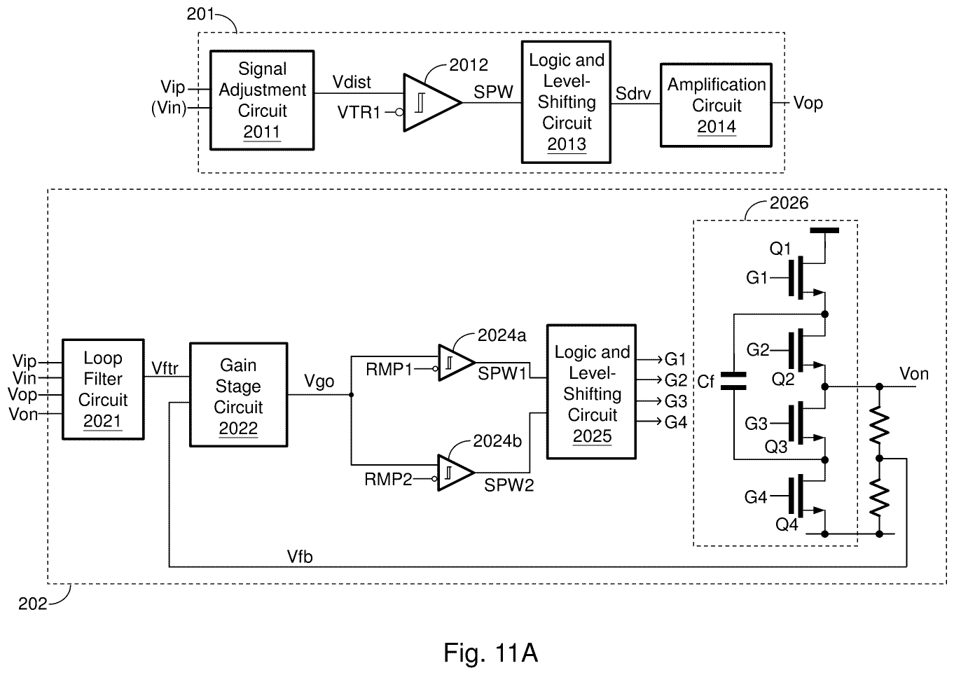

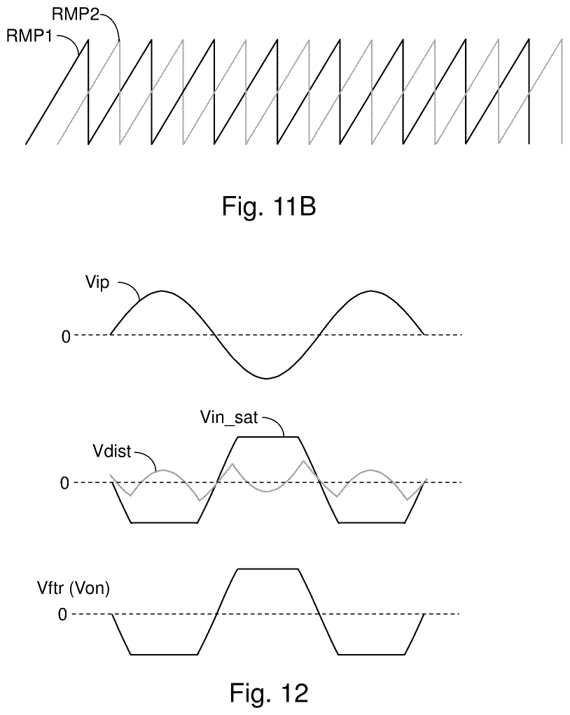

FIG. 11A shows a schematic diagram of the amplifier of the hybrid differential amplifier according to still another embodiment of the present invention. This embodiment is similar to the embodiment in FIG. 6, and differs in that, as shown in FIG. 11A, amplifier 202 is configured as a switched-capacitor converter. Specifically, in this embodiment, amplifier 202 includes pulse-width modulation circuits 2024a and 2024b, a logic and level-shifting circuit 2025, and a switched-capacitor power stage circuit 2026. The pulse-width modulation circuits 2024a and 2024b compare the gain output signal Vgo with plural ramp signals RMP1 and RMP2 to generate corresponding multiple pulse-width modulation signals SPW1 and SPW2. The logic and level-shifting circuit 2025 generates operation signals G1, G2, G3, and G4 for the switched-capacitor power stage circuit 2026 based on the multiple pulse-width modulation signals SPW1 and SPW2. The logic and level-shifting circuit 2025 also shifts the levels of the operation signals G1, G2, G3, and G4 to the required operating levels of the switched-capacitor power stage circuit 2026. The switched-capacitor power stage circuit 2026 includes plural switches Q1-Q4, which control switching of at least one capacitor Cf based on the multiple operation signals G1, G2, G3, and G4, thereby generating the second output signal Von through switched-capacitor power conversion.

FIG. 11B shows a schematic waveform diagram of signals related to the amplifier of the hybrid differential amplifier in FIG. 11A according to one embodiment of the present invention. The ramp signals RMP1 and RMP2 are shown in FIG. 11B. In this embodiment, the ramp signals RMP1 and RMP2 have a phase difference of 180 degrees from each other.

FIG. 12 shows a schematic waveform diagram of signals related to the hybrid differential amplifier according to one embodiment of the present invention. The first input signal Vip, the saturated amplification signal Vin_sat, the superposed signal of the first input signal Vip and the saturated amplification signal Vin_sat (i.e., the distortion amplification signal Vdist), and the loop filter signal Vftr are shown in FIG. 12. As shown in FIG. 12, since the saturated amplification signal Vin_sat is closer to a square wave, the distortion amplification signal Vdist resulting from the superposition of the saturated amplification signal Vin_sat and the first input signal Vip has a shorter interval near zero (the same applies to the second output signal Von). Therefore, in embodiments where the amplification stage circuit is a Class AB amplifier, the time during which current flows through both the upper and lower transistors simultaneously is shorter, thereby maintaining higher conversion efficiency compared to traditional Class D amplifiers while eliminating the need for an additional inductor.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A hybrid differential amplifier for generating a differential output signal based on a differential input signal to drive a load, the hybrid differential amplifier comprises:
a first amplifier, configured as an inductive switching converter, to perform pulse-width modulation (PWM) conversion based on a first input signal of the differential input signal to switch an inductor and generate a first output signal of the differential output signal; and
a second amplifier, configured to generate a second output signal of the differential output signal based on a second input signal of the differential input signal,
wherein the second amplifier is configured as a type of amplifier distinct from the inductive switching converter;
wherein the second amplifier further generates the second output signal based on feedback from the differential output signal, thereby rendering the differential output signal linearly correlated with the differential input signal.

2. The hybrid differential amplifier of claim 1, wherein the first amplifier comprises:
a signal adjustment circuit, configured to apply distortion processing to the first input signal to generate a distortion amplification signal;
a first pulse-width modulation circuit, configured to generate a PWM output signal based on a comparison between the distortion amplification signal and a first triangular wave; and
a switching power stage circuit, configured to switch the inductor based on the PWM output signal to generate the first output signal,
wherein the distortion processing includes: amplifying and clamping one of the first input signal or the second input signal to generate a saturated amplification signal, and linearly superposing the first input signal with the saturated amplification signal to generate the distortion amplification signal.

3. The hybrid differential amplifier of claim 1, wherein the second amplifier is configured as a linear amplifier operating in the continuous time domain, and the second amplifier includes:
a loop filter circuit, configured to linearly integrate the difference between a differential output signal and the differential input signal to generate a loop filter signal;
a gain stage circuit, configured to linearly amplify the loop filter signal to generate a gain output signal; and
an amplification stage circuit, configured to linearly amplify the gain output signal to generate the second output signal.

4. The hybrid differential amplifier of claim 3, wherein the second amplifier further includes:
an adder, configured to superpose the saturated amplification signal and the loop filter signal;
wherein the gain stage circuit is further configured to amplify the superposition of the saturated amplification signal and the loop filter signal to generate the gain output signal;
wherein a difference between the distortion amplification signal and the gain output signal is linearly correlated with the differential input signal.

5. The hybrid differential amplifier of claim 3, wherein:
the second output signal is fed back from the amplification stage circuit to the gain stage circuit; and
the gain stage circuit is further configured to generate the gain output signal based on a difference between a feedback signal related to the second output signal and the loop filter signal.

6. The hybrid differential amplifier of claim 2, wherein the signal adjustment circuit is configured in one of the following configurations:
configuration I: the signal adjustment circuit includes an in-phase amplification circuit and a clamping circuit, wherein:
the in-phase amplification circuit is configured to amplify one of the first input signal or the second input signal to generate an in-phase amplified signal; and
the clamping circuit is configured to limit the in-phase amplified signal within a predetermined range to generate the distortion amplification signal;
configuration II: the signal adjustment circuit includes an in-phase amplification circuit, a clamping circuit, and an inverted amplification circuit, wherein:
the in-phase amplification circuit is configured to amplify one of the first input signal or the second input signal to generate an in-phase amplified signal;
the clamping circuit is configured to limit the in-phase amplified signal within a predetermined range to generate a saturated amplification signal; and
the inverted amplification circuit is configured to amplify the saturated amplification signal to generate the distortion amplification signal;
configuration III: the signal adjustment circuit includes an in-phase amplification circuit, a clamping circuit, and an inverted adder circuit, wherein:
the in-phase amplification circuit is configured to amplify one of the first input signal or the second input signal to generate an in-phase amplified signal;
the clamping circuit is configured to limit the in-phase amplified signal within a predetermined range to generate a saturated amplification signal; and
the inverted adder circuit is configured to superpose the saturated amplification signal with the other of the first input signal or the second input signal to generate the distortion amplification signal.

7. The hybrid differential amplifier of claim 3, wherein the amplification stage circuit includes:
a Class AB amplifier which includes an upper transistor and a lower transistor; and
a level shifter, wherein the first and second ends of the level shifter are respectively configured to couple to the gate of the upper transistor and the gate of the lower transistor to maintain a preset voltage difference between the gates of the upper and lower transistors;
wherein the upper transistor and the lower transistor are connected in series and configured to generate the second output signal;
wherein the level shifter is further configured to shift the level of the gain output signal to control the gates of the upper and lower transistors.

8. The hybrid differential amplifier of claim 2, wherein the first pulse-width modulation circuit is configured to compare the distortion amplification signal with the first triangular wave to generate a first PWM signal, wherein the distortion amplification signal and the first triangular wave share the same common-mode level, wherein the hybrid differential amplifier further comprises:
a second pulse-width modulation circuit, configured to generate a second PWM signal based on a comparison between the distortion amplification signal and a second triangular wave, wherein a common-mode level of the first triangular wave and a common-mode level of the second triangular wave have a non-zero offset;
a load detection circuit, configured to determine whether the hybrid differential amplifier is in a light-load state or a non-light-load state and to generate a corresponding selection signal; and
an output selection circuit, configured to:
select the second PWM signal as the PWM output signal during the light-load state; and
select the first PWM signal as the PWM output signal during the non-light-load state.

9. The hybrid differential amplifier of claim 2, wherein the first pulse-width modulation circuit is configured to compare the distortion amplification signal with the first triangular wave to generate a first PWM signal, wherein the hybrid differential amplifier further comprises:
a second pulse-width modulation circuit, configured to generate a second PWM signal based on a comparison between the distortion amplification signal and a second triangular wave, wherein an amplitude of the first triangular wave is greater than an amplitude of the second triangular wave;
a load detection circuit, configured to determine whether the hybrid differential amplifier is in a light-load state or a non-light-load state and to generate a corresponding selection signal; and
an output selection circuit, configured to:
select the first PWM signal as the PWM output signal during the non-light-load state and control the switching power stage circuit to switch the inductor with a first amplitude to generate the first output signal, and
select the second PWM signal as the PWM output signal during the light-load state and control the switching power stage circuit to switch the inductor with a second amplitude to generate the first output signal;
wherein the first amplitude is greater than the second amplitude.

10. The hybrid differential amplifier of claim 2, wherein the second amplifier is configured as a switched capacitor converter, and the switched capacitor converter includes:
a loop filter circuit, configured to integrate a difference between the differential output signal and the differential input signal to generate a loop filter signal;
a gain stage circuit, configured to amplify a difference between the loop filter signal and a feedback signal related to the second output signal to generate a gain output signal;
a pulse-width modulation circuit, configured to generate plural PWM signals based on a comparison between the gain output signal and plural ramp signals; and
a switched-capacitor power stage circuit, including plural switches configured to control switching of at least one capacitor based on the plural PWM signals to generate the second output signal through switched-capacitor power conversion.

11. A hybrid differential amplification method for generating a differential output signal based on a differential input signal to drive a load, the method comprises:
performing pulse-width modulation (PWM) conversion based on a first input signal of the differential input signal to switch an inductor to generate a first output signal of the differential output signal;
generating a second output signal of the differential output signal based on a second input signal of the differential input signal, wherein the generation of the second output signal does not involve switching the inductor; and
generating the second output signal based on feedback from the differential output signal, thereby rendering the differential output signal linearly correlated with the differential input signal.

12. The hybrid differential amplification method of claim 11, wherein the step of generating the first output signal includes:
applying distortion processing to the first input signal to generate a distortion amplification signal;
generating a PWM output signal based on a comparison between the distortion amplification signal and a first triangular wave; and
switching the inductor based on the PWM output signal to generate the first output signal,
wherein the distortion processing includes: amplifying and clamping one of the first input signal or the second input signal to generate a saturated amplification signal, and linearly superposing the first input signal with the saturated amplification signal to generate the distortion amplification signal.

13. The hybrid differential amplification method of claim 12, wherein the step of generating the second output signal includes:
linearly integrating a difference between the differential output signal and the differential input signal to generate a loop filter signal;
linearly amplifying the loop filter signal to generate a gain output signal; and
linearly amplifying the gain output signal to generate the second output signal.

14. The hybrid differential amplification method of claim 13, wherein the step of generating the second output signal further includes:
amplifying the superposition of the saturated amplification signal and the loop filter signal to generate the gain output signal,
wherein a difference between the distortion amplification signal and the gain output signal is linearly correlated with the differential input signal.

15. The hybrid differential amplification method of claim 13, wherein the step of generating the second output signal further includes:
generating the gain output signal further based on a difference between a feedback signal related to the second output signal and the loop filter signal.

16. The hybrid differential amplification method of claim 12, wherein the step of generating the distortion amplification signal comprises one of the following:
amplifying one of the first input signal or the second input signal to generate an in-phase amplified signal, and limiting the in-phase amplified signal within a predetermined range to generate the distortion amplification signal;
amplifying one of the first input signal or the second input signal to generate an in-phase amplified signal, limiting the in-phase amplified signal within a predetermined range to generate a saturated amplification signal, and amplifying the saturated amplification signal to generate the distortion amplification signal; or
amplifying one of the first input signal or the second input signal to generate an in-phase amplified signal, limiting the in-phase amplified signal within a predetermined range to generate a saturated amplification signal, and superposing the saturated amplification signal with the other of the first input signal or the second input signal to generate the distortion amplification signal.

17. The hybrid differential amplification method of claim 13, wherein the step of generating the second output signal includes controlling a Class AB amplifier using the gain output signal, wherein:
the Class AB amplifier includes an upper transistor and a lower transistor;
controlling the Class AB amplifier includes shifting the level of the gain output signal to control the gates of the upper and lower transistors; and
maintaining a preset voltage difference between the gates of the upper and lower transistors.

18. The hybrid differential amplification method of claim 12, wherein the step of generating the first output signal further includes:
generating a first PWM signal by comparing the distortion amplification signal with the first triangular wave, wherein the distortion amplification signal and the first triangular wave have a same common-mode level;
generating a second PWM signal by comparing the distortion amplification signal with a second triangular wave, wherein the common-mode level of the first triangular wave and a common-mode level of the second triangular wave have a non-zero offset;
determining whether the differential input signal is in a light-load state or a non-light-load state; and
selecting the second PWM signal as the PWM output signal during the light-load state and selecting the first PWM signal as the PWM output signal during the non-light-load state.

19. The hybrid differential amplification method of claim 12, wherein the step of generating the first output signal further includes:
generating a first PWM signal by comparing the distortion amplification signal with the first triangular wave;
generating a second PWM signal by comparing the distortion amplification signal with a second triangular wave, wherein the amplitude of the first triangular wave is greater than the amplitude of the second triangular wave;
determining whether the differential input signal is in a light-load state or a non-light-load state;
selecting the first PWM signal as the PWM output signal during the non-light-load state and switching the inductor with a first amplitude to generate the first output signal; and
selecting the second PWM signal as the PWM output signal during the light-load state and switching the inductor with a second amplitude to generate the first output signal;
wherein the first amplitude is greater than the second amplitude.

20. The hybrid differential amplification method of claim 12, wherein the step of generating the second output signal further includes:
integrating a difference between the differential output signal and the differential input signal to generate a loop filter signal;
amplifying the difference between the loop filter signal and a feedback signal related to the second output signal to generate a gain output signal;
generating plural PWM signals based on a comparison between the gain output signal and plural ramp signals; and
controlling plural switches based on the plural PWM signals to switch at least one capacitor, thereby generating the second output signal through switched-capacitor power conversion.
